(19) United States
(12) Patent Application Publication
(10) Pub. No.: US 2004/0182316 A1
(43) Pub. Date: Sep. 23, 2004

(54) Processing equipment and processing method

(76) Inventor: Reiki Watanabe, Fukushima (JP)

Correspondence Address: LORUSSO & LOUD, 3137 Mount Vernon Avenue, Alexandria, VA, 22305, US

(21) Appl. No.: 10/743,314

(22) Filed: Dec. 23, 2003

(30) Foreign Application Priority Data
Dec. 26, 2002 (JP) 2002-378183

(51) Int. Cl. C23C 16/00

(52) U.S. Cl. 118/715; 427/248.1

(57) ABSTRACT

A processing equipment is provided with a vessel having one gas discharge port or more 12a to 15a, a substrate holder 4 provided in the vessel, and a rotating body 2 provided between the substrate holder 4 and a side wall 1 of the vessel to rotate around the substrate holder 4 and having one vent hole or notched vent portion or more, wherein a gas is discharged onto the substrate holder 4 from the gas discharge port 12a to 15a when the gas discharge port 12a to 15a coincides in position with the vent hole 16, or the like of the rotating body 2 by rotating the rotating body 2. Accordingly, there can be provided a processing equipment and a processing method capable of achieving reduction in time required for one cycle applied to laminate one atomic layer, making a computer control possible, facilitating maintenances including fitting and removal of parts of the equipment, and facilitating disassembly and cleaning of the equipment.

### BACKGROUND OF THE INVENTION

1. Field of the Invention

The present invention relates to a processing equipment and a processing method and, more particularly, a processing equipment and a processing method for performing film formation, etc. by an atomic layer deposition (ALD) method or an atomic layer epitaxy (ALE) method (referred simply to as an ALD method or an ALE method hereinafter) that is capable of depositing a layer on a substrate every atomic layer.

2. Description of the Prior Art

A thin film forming method based on the ALD method is disclosed in Patent Literatures 1 to 4, and Non-Patent Literatures 1, 2, etc. The thin film forming method based on the ALD method is the bottom-up type CVD thin film forming method. In this method, a chemical adsorption reaction is produced on a surface of the substrate by supplying a material gas (an element or a compound) onto the substrate whose temperature is raised, and thus the crystal is grown by depositing repeatedly many times every atomic layer or every molecular layer while utilizing a difference in a vapor pressure between the material and a target product, so that a thin film having a target thickness is formed. Atomic layers, etc. may be laminated by using the material gas of one type, or may be laminated alternately by using the material gas of two types or more. According to Non-Patent Literature 1, saturation conditions of deposition are produced by setting a temperature of the substrate in a temperature range called the ALD window, and then the atomic layer, or the like is deposited precisely layer by layer when the material gas is supplied onto the substrate.

In this method, since the atomic layer is formed every one layer carefully without fail on the surface of the substrate, generation of the crystal defect can be suppressed to the utmost and thus a thin film having a very good quality can be formed over a large area. Therefore, this technology is indispensable for next generation semiconductor chip, organic EL, liquid crystal, nano technology, etc., and thus such technology is very important not only industrially but also scientifically.

However, the ALD method is merely put to practical use of the display on the front panel of the car, etc., and has not been spread yet as technology for the semiconductor manufacturing as the greatest industry using the thin film.

The major cause for this is to take a very long time until a desired film thickness is obtained because the ALD method laminates the atomic layer carefully every one layer. For example, ten-thousand times to hundred-thousand times are required in lamination until a practical film thickness is obtained. In this case, since the existing ALD equipment needs a time of almost 1 second even in a quickest case to form one layer film, it takes several hours to one day to obtain a desired film thickness. For this reason, it is the existing state that the wide-spread practical use is put off as the semiconductor manufacturing technology of which a high production speed, i.e., a high throughput is required.

As one of solving means with respect to a much time consumption in film forming, there is adopted the substrate increased in a size and also a batch processing for processing a number of substrates arranged in the same chamber at a time as also set forth in Non-Patent Literature 1. In Non-Patent Literature 1, plural substrates are held in the plane direction or the vertical direction by the substrate holder that can be rotated upon a rotation axis, and then these substrates are moved sequentially to a plurality of material gas discharging portions provided around the rotation axis, so that the film is formed on these substrates every one atomic layer.

This batch processing method is suited to the process of the large glass substrate for the panel display, etc., for example. Also, with respect to the silicon wafer that has the largest diameter of 300 mm at a current point of time, there is mainly applied the batch processing capable of processing 25 to 50 substrates at a time.

In the case of the batch processing, the chamber of the ALD equipment is very large in size. In this chamber, there are repeated a plurality of cycles, each of which consists of introduction of a reaction gas X, adsorption of the reaction gas X onto the substrate, exhaust of a surplus gas, substitution of a process gas, exhaust of the process gas, introduction of a reaction gas Y, adsorption of the reaction gas Y onto the substrate, and exhaust of a surplus gas.

In the ALD equipment in which such processing is applied, there have arisen problems such that it takes much time to deposit one atomic layer, and further lack of uniformity in a reaction gas distribution is caused in the chamber so that the ALD conditions are not satisfied and thus the film formation becomes insufficient, etc.

Nowadays, such batch processing equipment is being replaced by the sheet-fed processing (single wafer processing) equipment for processing the silicon wafer one by one. This is because the sheet-fed type is superior in all respects of easy process change, handling, quality, etc. to the batch type in the present situation that a wafer size is gradually increased and 400 mm wafer is going to be employed in near future.

Meanwhile, an integration density of the silicon device is increased and thus a request for miniaturization is being shifted from a submicron level to a nano level. This is leading to studying at length the application of several tens to several hundreds atomic layers to the gate thin film, and so forth, and also requesting the technology to form such defect-free very thin film.

Also, in the industrial, official and academic semiconductor device researches, the functional material research, the nanotechnology, the biotechnology, etc., the thin film forming equipment is a tool indispensable for the research, etc. As such thin film forming equipment, there is now employed mainly the vacuum deposition equipment, the sputter equipment, the film forming equipment for forming the film by the physical approach such as the laser ablation, or the like, or the film forming equipment applied recently to the CVD (Chemical Vapor Deposition) method of forming the thin film by depositing the molecules and the atoms that are generated by the method of introducing the molecular gas onto the substrate to cause the chemical change by thermal decomposition, plasma decomposition, or the like.

However, the ALD equipment has not been spread as the thin film forming tool for the research and development in various research institutions. The major reasons for this are that the ALD equipment is expensive, the large-size batch type is in the mainstream, its handling is complicated, and adversely it takes very long time to form the film.

(Patent Literature 1)

Patent Application Publication (KOKAI) 2002-4054

(Patent Literature 2)

U.S. Pat. No. 5,879,459

(Patent Literature 3)

U.S. Pat. No. 6,174,377

(Patent Literature 4)

U.S. Pat. No. 6,387,185

(Non-Patent Literature 1)

Handbook of Thin Film Process Technology, B1.5:1-B1.5:17, 1995 IOP Publishing Ltd'

(Non-Patent Literature 2)

Electronic Material, July 2002, p.29-p.34

As described above, in the ALD equipment in the prior art, there existed a problem that it takes a long time for one cycle until one atomic layer is formed. Under the existing state, in order to cover up this disadvantage, the batch type is in the mainstream and thus the equipment is increased in size. Therefore, there is desired the ALD equipment of the sheet-fed type capable of reducing a size of the equipment and the ALD equipment capable of enhancing sufficiently a throughput.

Also, it is desired that the film should be formed under the computer control, while utilizing positively the feature of the ALD method that can deposit one atomic layer in one cycle by adjusting simply the film forming conditions when the film is formed in the saturation condition.

In addition, as set forth in Non-Patent Literature 2, the ALD material is the unstable compound in which decomposition, deterioration, etc. occur readily due to the moisture, etc. in the air. In particular, since the ALD material in the High-k thin film application is reformed into the solid content, which is nonvolatile and insoluble in the cleaning solvent, by the influence of moisture, the ALD equipment must be disassembled and cleaned. If the ALD equipment has complicated valves, narrow pipings, etc., the disassembling and the cleaning of the ALD equipment become very troublesome.

### SUMMARY OF THE INVENTION

It is an object of the present invention to provide a processing equipment and a processing method capable of achieving reduction in time required for one cycle applied to laminate one atomic layer, making a computer control possible, facilitating maintenances including fitting and disassembling of parts of the equipment, and facilitating disassembling and cleaning of the equipment.

The processing equipment of the invention comprises the vessel having one gas discharge port or more, the substrate holder provided in the vessel to load the substrate thereon, and the rotating body provided between the substrate holder and the side wall of the vessel to rotate around the substrate holder and having one vent hole or notched vent portion or more, wherein the gas is discharged onto the substrate holder from the gas discharge port when the gas discharge port coincides in position with the vent hole or notched vent portion of the rotating body by rotation control of the rotating body.

In other words, the rotating body has a gas switching function during its rotation. Therefore, in case this processing equipment is applied to the film formation, the same layers or different layers can be formed in a multi-layered fashion while controlling a film thickness. Also, in case this processing equipment is applied to the etching equipment, an amount of discharged etching gas can be controlled. Accordingly, multiple layers can be etched with good controllability.

In particular, in the situation that the processing equipment of the present invention is applied to the ALD equipment, if the reaction gas discharge port is provided as one gas discharge port or more, the atomic layer can be deposited every layer by the rotation of the rotating body. Also, if the rotating direction of the rotating body is appropriately adjusted, a deposition order, etc can be appropriately changed and thus the film structure can be adjusted appropriately. In addition, a deposition speed can be adjusted simply merely by adjusting the rotational speed of the rotating body. Further, if a dopant atomic layer is deposited, for example, so as to put it between deposition layers made of a semiconductor layer by using a dopant gas as one of the reaction gases, the semiconductor film with n-type or p-type conductivity can be formed. Further, if the reaction gas discharge port and the purge gas discharge port are provided and arranged alternately around the substrate holder, the deposition of one atomic layer and the purge of the reaction gas can be executed alternately. Since the purge of the reaction gas is executed in a moment, a film forming speed can be improved.

Also, since the rotating body is not fixed, such rotating body can be simply disassembled and thus it is capable of facilitating the disassembling/cleaning of the rotating body and the equipment including the gas supplying side. In addition, it is capable of facilitating the cleaning of the inside of the film forming chamber including the gas piping system after the rotating body is removed.

In addition, the clearance between the rotating body and the side wall of the vessel can be adjusted while floating the rotating body over the side wall of the vessel. Therefore, if the vessel and the rotating body are formed at first with good consistency, it is capable of facilitating mutual positional alignment between the vessel and the rotating body, and maintaining a very narrow clearance.

Further, it is further provided with means for adjusting a pressure of the gas (reaction gas and the purge gas) and suppressing pressure variation of the gases discharged from the gas discharge ports. Therefore, when discharge and non-discharge of these gases are repeated by rotating the rotating body, variation in the gas pressure at the time of discharge and non-discharge can be suppressed. As a result, the rotating body can be prevented from being affected by the pressure variation and accordingly the stable clearance can be assured. Also, an amount of the gas that flows in when the vent hole, etc. coincides with the gas discharge port can be kept constant by suppressing the pressure variation.

Moreover, in the processing method of the present invention, the gas is discharged onto the substrate from the gas discharge port when the gas discharge port coincides with the vent hole, or the like of the rotating body by controlling the rotation of the rotating body. Therefore, an amount of discharged gas can be controlled with good precision and therefore the film thickness control and the etching control can be executed with good precision.

In particular, in case the processing method of the present invention is applied to the ALD method, the reaction gas discharge port and the purge gas discharge port are provided as one gas discharge port or more and arranged alternately around the substrate holder, and then discharge of the reaction gas and discharge of the purge gas are executed alternately by controlling the rotation of the rotating body. Therefore, the reaction gas remaining on the substrate can be exhausted in a moment by discharging the purge gas after one atomic layer is deposited by discharging the reaction gas. As a result, one atomic layer or more can be deposited at a high speed.

### BRIEF DESCRIPTION OF THE DRAWINGS

FIG. 1 is a side view showing an overall configuration of an ALD equipment as a first embodiment of the present invention;

FIG. 2 is a perspective view showing respective structures of a reduced pressure vessel, a rotating body, and a substrate holder and their mutual arrangement in the ALD equipment as the first embodiment of the present invention;

FIG. 3 is a sectional view showing a structure of a vent hole for introducing a reaction gas in the ALD equipment as the first embodiment of the present invention;

FIG. 4 is a sectional view showing structures of a piping and a vent hole for introducing the reaction gas in the ALD equipment as the first embodiment of the present invention;

FIGS. 5A and 5B are a sectional view and a plan view showing a structure of a rotating means of a rotating body in the ALD equipment as the first embodiment of the present invention;

FIG. 6 is a perspective view showing another structure of the rotating body in the ALD equipment as the first embodiment of the present invention;

FIGS. 7A to 7C are sectional views showing still another structure of the rotating body in the ALD equipment as the first embodiment of the present invention;

FIG. 8 is a sectional view showing another exhausting method in the ALD equipment as the first embodiment of the present invention;

FIG. 9 is a sectional view showing still another exhausting method in the ALD equipment as the first embodiment of the present invention;

FIG.10A is a sectional view showing another connecting method from a floating gas supply source to a fourth vent hole in the ALD equipment as the first embodiment of the present invention, and FIG. 10B is a sectional view showing another mechanism for controlling a partial pressure of a floating gas;

FIGS. 11A to 11H are plan views showing a film forming method using the ALD equipment as the first embodiment of the present invention;

FIGS. 12A to 12E are timing charts showing gas flows into a film forming chamber in the film forming method using the ALD equipment as the first embodiment of the present invention;

FIGS. 13A and 13B are sectional views showing the film forming method using the ALD equipment as the first embodiment of the present invention;

FIGS. 14A and 14B are plan views showing a structure of a gas supplying portion into a film forming chamber of an ALD equipment as a second embodiment of the present invention; and

FIGS. 15A and 15B are sectional views showing a film forming method using the ALD equipment as the second embodiment of the present invention.

### DETAILED DESCRIPTION OF THE PREFERRED EMBODIMENTS

Embodiments of the present invention will be explained with reference to the drawings hereinafter.

### First Embodiment

### (i) Configuration of the ALD Equipment

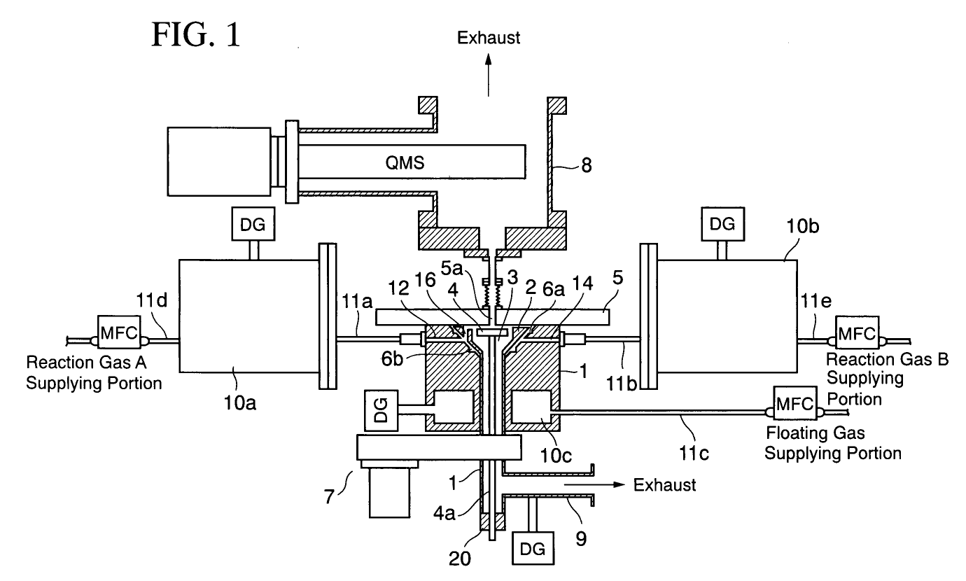

FIG. 1 is a side view showing an overall configuration of an atomic layer deposition equipment or an atomic layer epitaxy equipment (referred to as an ALD equipment or an ALE equipment hereinafter) according to, a first embodiment of the present invention.

As shown in FIG. 1, the overall configuration of the ALD equipment comprises a reduced pressure vessel separated from the outside by a side bulkhead 1, an upper bulkhead 5 and a lower bulkhead 20, a cone-like shape rotor (rotating body) 2 which is provided in the reduced pressure vessel and can be rotated along the side bulkhead 1 in both rightward and leftward directions, a substrate holder 4 which is provided on the inside of the rotor 2 and is supported by a supporting shaft 4a, and a means 7 for rotating the rotor 2. A space of an inner side of the rotor 2 and a space between the substrate holder 4 and the upper bulkhead 5 constitute a film forming chamber 3. The upper bulkhead 5 is made of transparent material, and thus it is capable of observing an interior of the reduced pressure vessel, especially the film forming chamber 3 therethrough.

Also, the equipment is provided with an exhaust piping 8 connected to the upper bulkhead 5 of the reduced pressure vessel and an exhaust piping 9 connected to a lower portion of the side bulkhead 1. In particular, a mass spectrometer (QMS) is arranged in the upper exhaust piping 8 to monitor the type of gas introduced into the film forming chamber 3 and chemical reaction information. Exhausting means (not shown) are connected to the exhaust pipings 8, 9 respectively. Here, a means for observing the film forming situation, an energy supply source for smoothing/facilitating the film formation, a lamp heating means as a substrate heating means, a catalyst plate for activating the gas, a plasma generating means, or the like can be fitted over the substrate holder 4. In this case, an appropriate space is provided between the upper bulkhead 5 and the substrate holder 4 by omitting the upper exhaust piping 8 and the mass spectrometer (QMS) appropriately and disposing the upper bulkhead 5 much more to the upper side.

In addition, in order to introduce reaction gases A, B into the reduced pressure vessel respectively, two vent holes (first vent holes) 12, 14 are provided in the side bulkhead 1 of the reduced pressure vessel. Two vent holes 12, 14 are terminated at inner openings (gas discharge ports) on an inner surface of the side bulkhead 1 respectively. Also, although not explicitly shown in FIG. 1, in order to introduce purge gases P1, P2 into the reduced pressure vessel, two vent holes (second vent holes) are provided similarly in the side bulkhead 1 of the reduced pressure vessel. Two vent holes for introducing the purge gases P1, P2 are terminated at different inner openings (gas discharge ports) on the inner surface of the side bulkhead 1 respectively. The inner openings of two vent holes 12, 14 for introducing the reaction gases A, B respectively and the inner openings of two vent holes for introducing the purge gases P1, P2 respectively are arranged around the substrate holder 4 alternately every 90 degree in a manner such that the order is constituted by the inner opening of the vent hole 12 for the reaction gas A, the inner opening of the vent hole for the purge gas P1, the inner opening of the vent hole 14 for the reaction gas B, and the inner opening of the vent hole for the purge gas P2.

Also, reservoirs 10a, 10b, 10d, 10e are provided in the middle of pipings extended from gas supply portions of the reaction gases A, B and the purge gases P1, P2 to corresponding gas discharge ports respectively. In this case, in FIG. 1, the reservoirs 10d, 10e for the purge gas are not explicitly shown and only their reference symbols are given.

The reservoirs 10a, 10b, 10d, 10e have a function of reducing a gas pressure. Accordingly, the rotor 2, which is rotated as floating and has a shutter function, is not subject to a very strong pressure from the gas introduced to the shut gas discharge ports. In addition, since a differential pressure between the reservoirs 10a, 10b, 10d, 10e and the film forming chamber 3 is lowered as the result of reduction in the pressure caused by the reservoirs 10a, 10b, 10d, 10e, pipings for two vent holes (first vent holes) 12, 14 and pipings for two vent holes for introducing the purge gases P1, P2 are made larger in diameter to some extent. It is in order to prevent an amount of the gas introduced when the vent holes of the rotor 2 coincide with the gas discharge ports from being not extremely reduced.

Also, the reservoirs 10a, 10b, 10d, 10e have a function of preventing a variation in gas pressure of the reaction gases A, B and the purge gases P1, P2 during an operation of the ALD equipment, even at the time of the discharge and the discharge stop of the gases into the film forming chamber 3. Accordingly, the floated rotor 2 is prevented from undergoing the pressure variation from the reaction gases A, B and the purge gases P1, P2, as described later, so that a stable clearance can be kept.

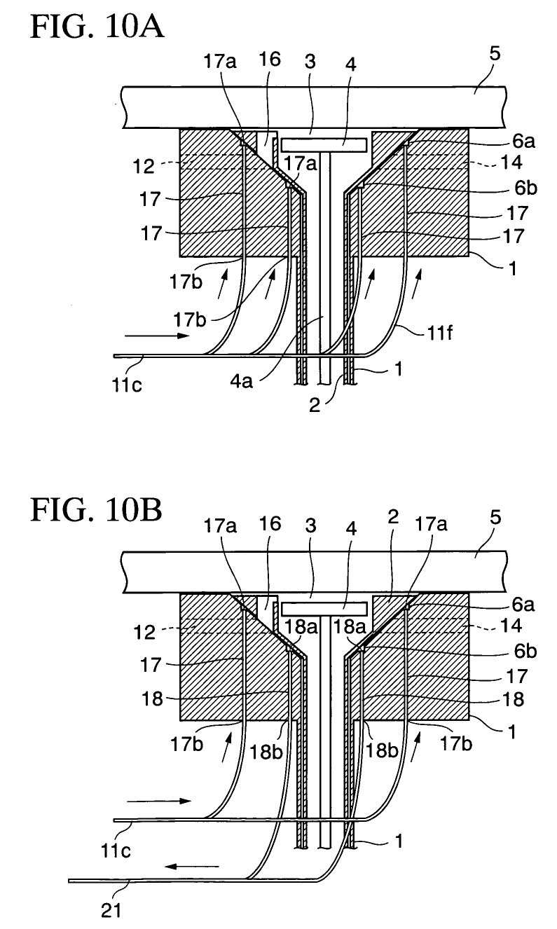

Also, although not shown in FIG. 1, a fourth vent hole for introducing a floating gas, which floats the rotor 2 over the side bulkhead 1, into a clearance between the side bulkhead 1 and the rotor 2 is provided in the side bulkhead 1 of the reduced pressure vessel. A floating gas supplying portion is connected to an outer opening of the fourth vent hole via a reservoir 10c. Here, since a gas pressure of the floating gas is not so varied during the operation of the equipment in contrast to the reaction gases and the purge gases, the reservoir 10c for the floating gas can be omitted and then a piping 11c can be connected directly to an outer opening 17b of the fourth vent hole 17, as shown in FIG. 10A.

In this case, in FIG. 1, a symbol “DG” denotes a pressure gauge. The pressure gauges are provided to the reservoirs 10a, 10b, 10d, 10e and the lower exhaust piping 9 respectively. Also, a symbol “MFC” denotes a mass flow controller. The mass flow controller has a function of adjusting a flow rate of the gas flowing through the piping. The MFCs are provided to the pipings 11c, 11d, lie for the reaction gas, the purge gas, and the floating gas respectively.

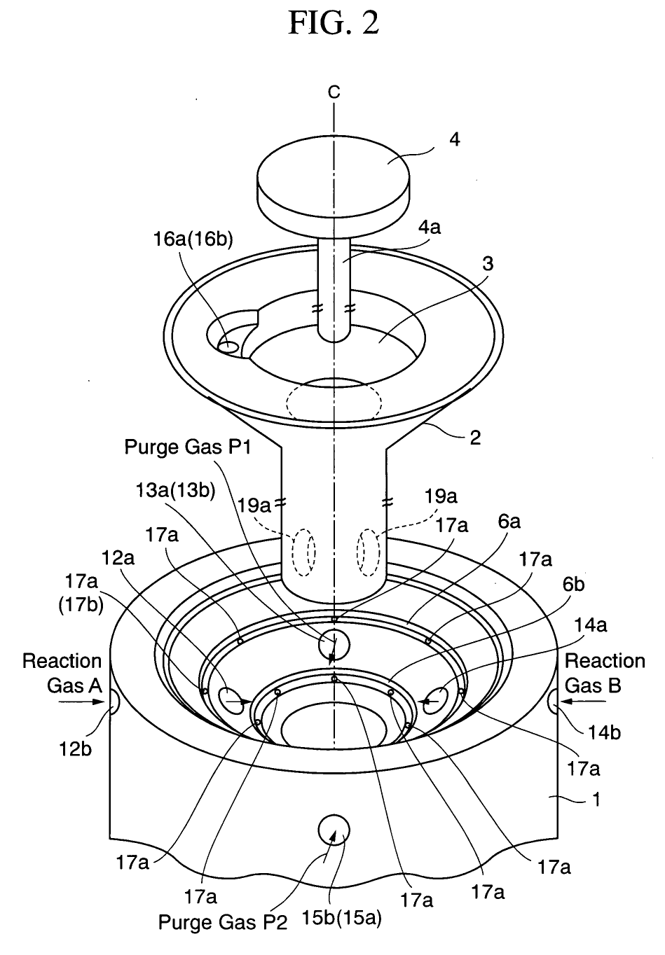

Next, detailed structures of the side bulkhead 1 of the reduced pressure vessel, the rotor (rotating body) 2, and the substrate holder 4 and their mutual arrangement in the ALD equipment will be explained with reference to FIG. 2 hereunder. FIG. 2 is a perspective view, and shows a state in which the rotor 2 and the substrate holder 4 are extracted upwardly from the reduced pressure vessel along the same center axis C for convenience of explanation.

As shown in FIG. 2, the reduced pressure vessel has a cone-like shape in at least an upper inner surface of the side bulkhead 1 of which is expanded upward, and an inner surface of the reduced pressure vessel is formed symmetrically with respect to the center axis C.

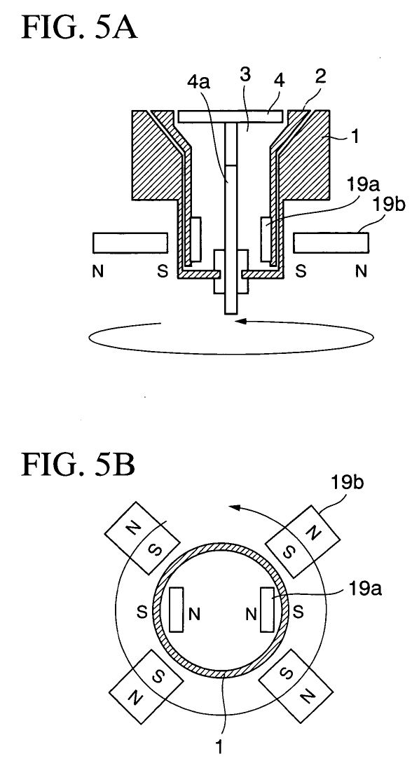

The rotor 2 has a cone-like shape whose upper outer surface is expanded upward in conformity with the shape of the inner surface of the side bulkhead 1, and an outer surface of the rotor 2 is formed symmetrically with respect to the center axis C. The rotor 2 is floated by the floating gas and is rotated upon the center axis C in both rightward and leftward directions along the inner surface of the side bulkhead 1 of the reduced pressure vessel. In this case, in FIG. 2, a symbol 19a denotes an internal magnet provided to be fixed to a lower portion of the rotor 2. As described with reference to FIGS. 5A and 5B later, these internal magnets 19a contribute to the rotation of the rotor 2.

Also, the substrate holder 4 is supported by the supporting shaft 4a and is provided on the inner side of the rotor 2. Then, the substrate holder 4 has a substrate loading surface that is approximately perpendicular to the center axis C, and the substrate is loaded on the substrate loading surface and is fixed by the electrostatic chuck, the vacuum chuck, or the like. Then, a heater is built in the substrate holder 4, and the substrate can be heated by the heater.

Four vent holes are formed so as to pass through the side bulkhead 1. That is, those are the first vent holes 12, 14 for introducing the reaction gases A, B respectively and the second vent holes for introducing the purge gases P1, P2 respectively. Respective vent holes are terminated at inner openings (gas discharge ports) 12a to 15a on the inner surface of the cone-shaped portion of the side bulkhead 1, and terminated at outer openings 12b to 15b on the outer surface of the side bulkhead 1. The inner openings 12a to 15a of the first and second vent holes 12 to 15 are alternately arranged at an angular interval of 90 degree along a circumference around the center axis. In this case, although elements indicated by the symbols in parentheses in FIG. 2 are not explicitly shown in FIG. 2, 13b among the symbols shows an outer opening of the vent hole for the purge gas P1 terminated at the outer surface of the side bulkhead, 15a shows an inner opening of the vent hole for the purge gas P2 terminated at the inner surface of the side bulkhead, and 17b shows the outer opening of the vent hole for the floating gas.

Supplying portions of the reaction gases A, B are connected to the outer openings 12b, 14b of two first vent holes 12, 14 respectively. The first vent holes 12, 14 guide the reaction gases A, B from the outer openings 12b, 14b to the inner openings 12a, 14a respectively. In addition, supplying portions of the purge gases P1, P2 are connected to the outer openings 13b, 15b of two second vent holes respectively. The second vent holes guide the purge gases P1, P2 from the outer openings 13b, 15b to the inner openings 13a, 15a respectively.

Also, a third vent hole 16 is provided in the rotor 2. The third vent hole 16 is passed through the rotor (rotating body) 2 in the vertical direction, is terminated at an outer opening 16b on the outer surface of the rotor 2, and is terminated at an inner opening 16a on the inner surface of the rotor 2 in this embodiment. The inner opening 16a of the third vent hole 16 is provided at a position that comes beside the substrate holder 4 when the substrate holder 4 is set. An interior of the rotor 2 serves as the film forming chamber 3. When the rotor 2 is rotated and the reaction gas supplying portions and the interior of the film forming chamber 3 are connected to each other via the first vent holes 12, 14 and the third vent hole, the reaction gases A, B are passed through the third vent hole upwardly and are discharged onto the substrate holder 4. When the purge gas supplying portions and the interior of the film forming chamber 3 are connected to each other via the second vent holes and the third vent hole, the purge gases P1, P2 are passed through the third vent hole upwardly and are discharged onto the substrate holder 4.

Also, eight fourth vent holes for introducing the floating gas are provided in the side bulkhead 1. One end of each of the fourth vent holes is terminated at an inner opening (gas discharge port) 17a on the inner surface of the cone-shaped portion of the side bulkhead 1, and the other end thereof is terminated at the outer opening 17b on the outer surface of the side bulkhead 1. Also, stripe-like concave portions 6 acting as the gas reservoir of the floating gas respectively are provided on the inner surface of the cone-shaped portion of the side bulkhead 1 and in upper and lower stripe-like areas provided at two locations along the circumference around the center axis C. The inner openings 17a of fourth vent holes 17 are arranged in each stripe-like concave portion 6 at an equal interval at four locations along the circumference.

The floating gas supplying portion is connected to the outer openings 17b of the fourth vent holes 17. These fourth vent holes 17 guide the floating gas from the outer openings 17b to the inner openings 17a. When the floating gas is discharged from the inner openings 17a of the fourth vent holes 17 into the clearance between the side bulkhead 1 of the reduced pressure vessel and the rotor (rotating body) 2, the rotor 2 is floated so as to keep a predetermined distance (clearance) with respect to the side bulkhead 1. This distance can be adjusted mainly by a weight of the rotor 2 and the pressure of the floating gas. Because this distance affects generation of the so-called pneumatic hammer phenomenon and the leakage of the reaction gases into the outer side of the film forming chamber 3 and the leakage of the floating gas into the inner side of the film forming chamber 3, such distance must be adjusted satisfactorily. Here, the pneumatic hammer phenomenon signifies a self-oscillation caused due to the compressibility of the gas.

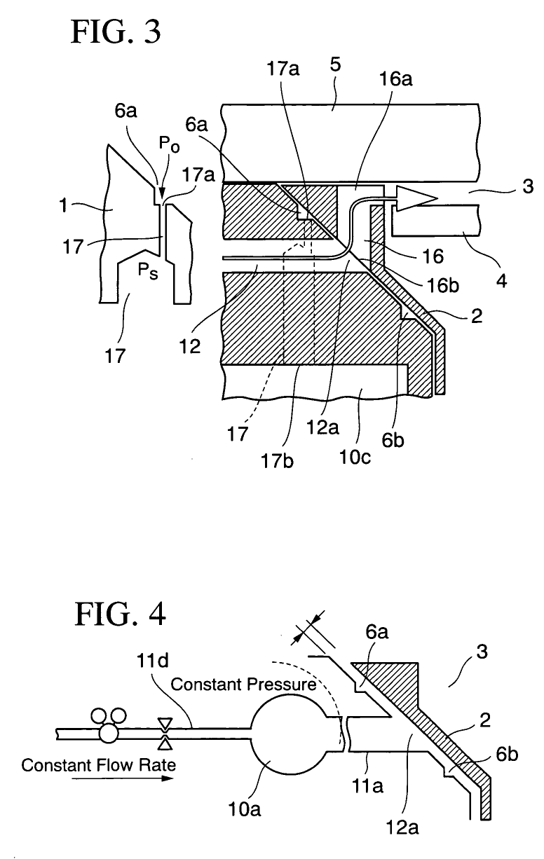

Next, FIG. 3 is a sectional view showing a state in which the outer opening 16b of the third vent hole 16 in the rotor (rotating body) 2 is moved to the side of the inner opening 12a of the first vent hole 12 in the side bulkhead 1 according to the rotation and thus the reaction gas A supplying portion and the interior of the film forming chamber 3 are connected mutually. Also, such a behavior is also shown in FIG. 3 that the inner opening 17a of the fourth vent hole 17 for introducing the floating gas is terminated at the stripe-like concave portions (gas reservoirs) 6a, 6b formed on the inner surface of the rotor 2.

As shown in FIG. 3, when the rotor 2 is rotated and the reaction gas supplying portions and the interior of the film forming chamber 3 are connected to each other via the first vent holes 12, 14 and the third vent hole 16, the reaction gases A, B are discharged onto the substrate holder 4. When the purge gas supplying portions and the interior of the film forming chamber 3 are connected to each other via the second vent holes and the third vent hole 16, the purge gases P1, P2 are discharged onto the substrate holder 4.

In this case, a turn-down ratio (Po/Ps) of the fourth vent hole 17 is set appropriately to generate a differential pressure that causes the rotor 2 to float over the side bulkhead 1.

In addition, as shown in FIGS. 5A and 5B, a plurality of permanent magnets 19a are provided on the inner side of the rotor 2 so as to direct their S poles to the outer side. A plurality of permanent magnets 19b that can rotate integrally in both rightward and leftward directions are provided around the outer periphery of the side bulkhead 1 so as to direct their S poles to the side bulkhead 1 side of the reduced pressure vessel.

A relative position of the rotor 2 with respect to the outer permanent magnets 19b is fixed by a repulsive force that acts between the outer permanent magnets 19b provided on the periphery of the reduced pressure vessel and the inner permanent magnets 19a. In addition, the rotor 2 in which the inner permanent magnets 19a are provided is rotated upon the center axis C in both rightward and leftward directions according to the integral rotation of the outer permanent magnets 19b along the periphery of the side bulkhead 1 of the reduced pressure vessel.

Further, a controlling means for adjusting at least one of partial pressures of the reaction gases A, B, partial pressures of the purge gases P1, P2, a partial pressure of the floating gas, an amount of exhaust from the vessel, the rotating direction of the rotor 2, a rotational speed of the rotor 2, and a total number of revolution of the rotor 2 from a start of the film formation to an end thereof may be provided. The controlling means comprises various kinds of measuring devices for above values to be controlled, and a central processing unit or partial processing units such as micro-computer, etc. for supplying control signals to electronic controlling circuits and mechanism on the basis of the measured values. Thus, automatic deposition control can be carried out.

In this case, the material having a resistance against heat in heating the substrate and cleaning chemicals, e.g., stainless, quartz glass, Pyrex glass, ceramics, etc. may be selected and employed appropriately, as respective materials of the upper bulkhead 5, the side bulkhead 1, and the lower bulkhead 20 of the reduced pressure vessel, material of the rotor (rotating body) 2, and material of the substrate holder 4.

As described above, the ALD equipment of the embodiment of the present invention is provided with the reaction gas discharge ports and the purge gas discharge ports which are arranged alternately along the periphery of the substrate, and the rotor 2 that has the vent hole at a location between the reaction gas discharge ports, etc. and the substrate and is rotated around the substrate in both rightward and leftward directions. And then this rotor 2 is used as a means for switching the reaction gases and the purge gases.

The discharge of the reaction gas and the discharge of the purge gas can be carried out alternately by controlling the rotation of the rotor 2. Accordingly, the purge gas still remaining on the substrate after one atomic layer is deposited by discharging the reaction gases can be exhausted in an instant by the discharge of the purge gas. As a result, a large number of atomic layers can be deposited at a high speed.

Also, the vent hole 17 for the floating gas is provided in the side bulkhead 1, and the floating gas can be discharged from the inner opening 17a to the clearance between the rotor 2 and the side bulkhead 1. Therefore, the rotor 2 can be rotated while the rotor 2 can be floated over the side bulkhead 1. As a result, since mechanical contact can be avoided to rotate the rotor 2, it results in preventing wear of the side bulkhead 1, the rotor 2, etc. and contamination of the interior of the film forming chamber 3 due to particles generated by the wear.

Also, since the rotor 2 is provided separately from the side bulkhead 1, the substrate holder 4, etc., disassembling of the rotor 2 can be executed simply. And then it results in facilitating the cleaning of the rotor 2, and also it results in facilitating the cleaning of mechanism of the gas supplying side including the inside of the reduced pressure vessel and the substrate holder 4, etc. after the rotor 2 is removed.

Also, the clearance is adjusted by floating the rotor 2 over the side bulkhead 1. For this reason, if the vessel and the rotor 2 are formed at first with good consistency, mutual positional alignment such as an axis alignment between the rotor 2 and the side bulkhead 1, etc. becomes easy when parts are assembled again after they are disassembled to execute the cleaning, etc., and thus the stable and very narrow clearance can be implemented.

### (ii) Film Forming Method Using the ALD Equipment

Next, a method of forming the film on the substrate by using the above ALD equipment will be explained with reference to the drawings hereunder.

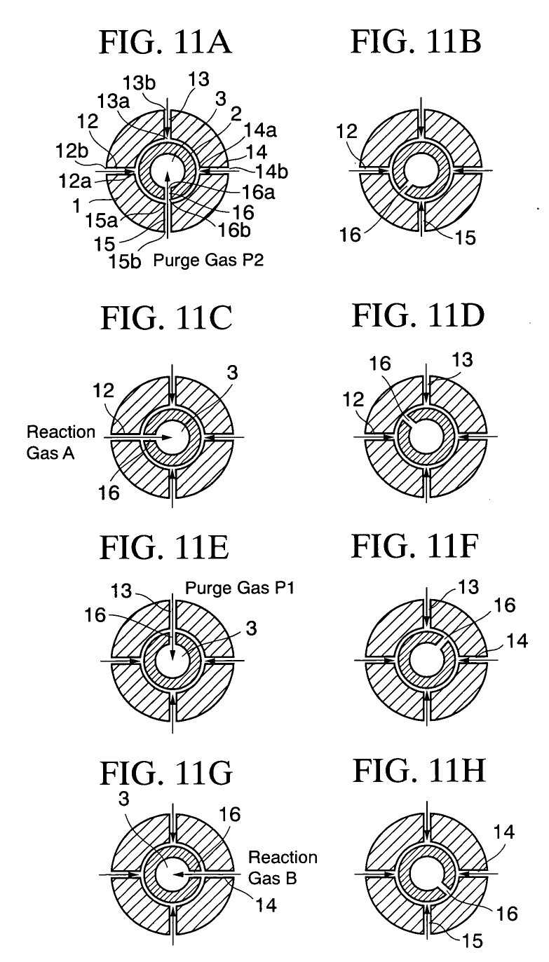

FIGS. 11A to 11H are plan views, in which the film forming chamber 3 is observed from the upper side of the ALD equipment, for explaining a method of depositing the film on the substrate every one atomic layer. Those depict a motion of the rotor (rotating body) 2, which rotates upon the center axis, and flows of the reaction gases and the purge gases. In this film forming method, an assumption is performed for forcing the rotor (rotating body) 2 to rotate only in the rightward direction. Also, an assumption is performed for using two different reaction gases out of the reaction gases recited in the following. These reaction gases are generalized and indicated as A, B in the following explanation.

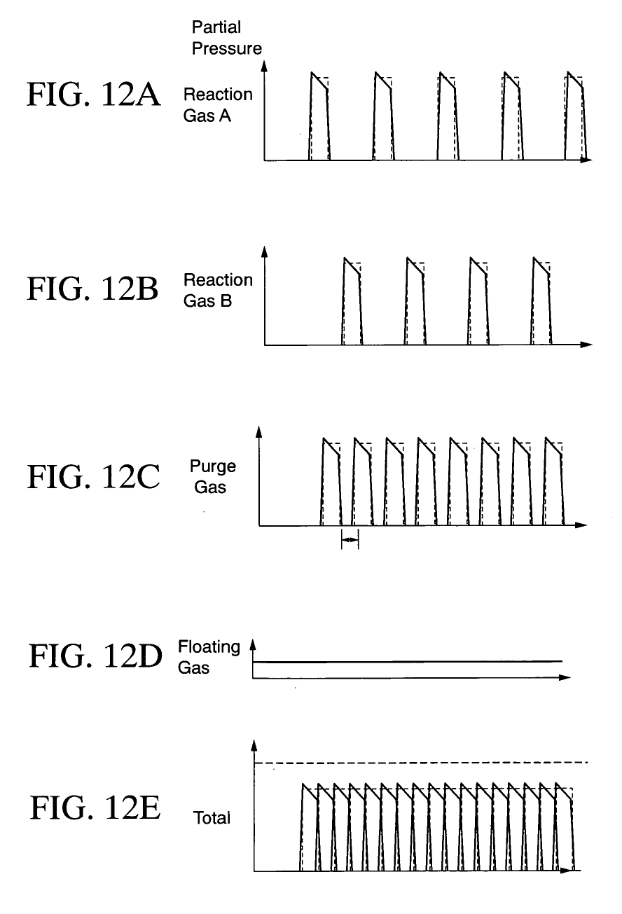

FIGS. 12A to 12D are timing charts showing respective partial pressures of the reaction gases A, B carried by the carrier gas, the purge gases P1, P2, and the floating gas during the operation of the above ALD equipment in the film forming chamber 3. FIG. 12E is a timing chart showing a total pressure change in the film forming chamber 3. Nitrogen is used as the purge gases P1, P2 and the floating gas.

Here, in FIGS. 12A to 12E, a gradual reduction in a partial pressure at a high level corresponds to reduction in the partial pressure caused by the exhaust only, while a sharp reduction in the partial pressure corresponds to reduction in the partial pressure caused by the forced exhaust of an unnecessary gas by the purge gas. A period during high partial pressures of respective gases in the film forming chamber 3 is almost 1/4 of a rotating period of the rotor 2. The floating gas flows into the film forming chamber 3 in no small quantities. However, since this quantity is constant, concentrations of reaction material quantities in the film forming chamber 3 can be kept appropriate by previously enhancing concentrations of reaction materials in the reaction gases based on this constant quantity.

It is understood based on the flowcharts in FIG. 12A to 12E how inflow/outflow of respective gases into/from the film forming chamber 3 are changed. That is, if the rotating period is assumed as 1 second, the reaction gases A, B stays only for about 0.25 second in the film forming chamber 3 and then they are exhausted substantially perfectly almost in a moment from the film forming chamber 3 by the introduction of the purge gases P1, P2. It was confirmed experimentally that a quantity of residual gas is reduced abruptly in the order of about 3 to 4 figures by introducing the purge gases P1, P2.

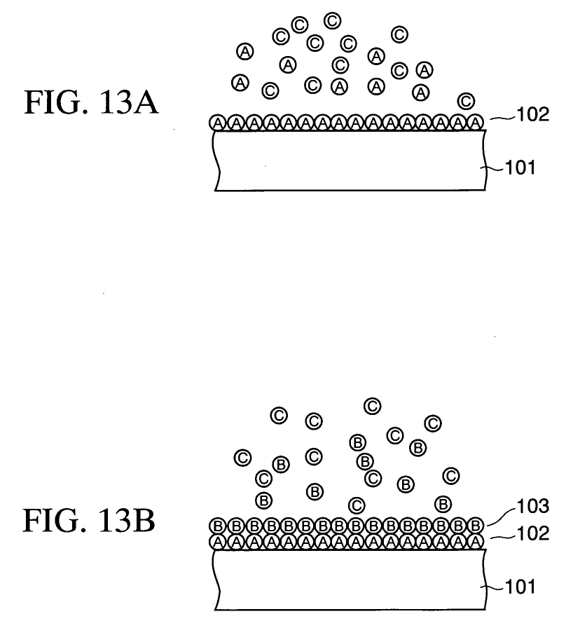

Also, FIGS. 13A and 13B are sectional views showing a behavior that the film is deposited on a substrate 101 every atomic layer. Here, in FIGS. 13A and 13B, a symbol A denotes an A atom of the reaction gas A, a symbol B denotes a B atom of the reaction gas B, and a symbol C denotes an atom or a molecule of the carrier gas.

In the film forming method using the ALD equipment, first the upper bulkhead 5 of the ALD equipment in FIG. 1 is opened, and the substrate 101 is loaded on a loading surface of the substrate holder 4 and then fixed by the electrostatic chuck, or the like. Then, the interior of the film forming chamber 3 is tightly sealed by closing the upper bulkhead 5. Then, the heater built in the substrate holder 4 is set to an appropriate temperature in a temperature range of 20 to 1200° C. in response to the type of the reaction gas to heat the substrate. In this case, the temperature is set to the temperature condition that corresponds to the ALD window range of the reaction gases A, B.

Then, the interior of the reduced pressure vessel is exhausted by the exhausting apparatus. After the interior of the reduced pressure vessel reaches a predetermined pressure, the floating gas whose gas pressure is adjusted to an appropriate pressure in a range of several hundreds Pa to several ten-thousands Pa is supplied to the fourth vent hole 17 to float the rotor 2 over the side bulkhead 1 of the reduced pressure vessel. In this case, if the pressure of the floating gas is set too high, the clearance becomes very large and also the partial pressure of the floating gas in the film forming chamber 3 becomes excessively large. Therefore, the pressure of the floating gas must be lowered appropriately.

Then, the reaction gas A is supplied to the outer opening 12b connected to the vent hole 12 in the side bulkhead 1, and also the reaction gas B is supplied to the outer opening 14b connected to the vent hole 14 in the side bulkhead 1. As the case may be, the carrier gases for the reaction gases A, B are used. Then, partial pressures of the reaction gases A, B are set to appropriate pressures in a range of 1 Pa to 10 Pa respectively. Also, the purge gases P1, P2 are supplied to the outer openings 13b, 15b connected to the vent holes 13, 15 in the side bulkhead 1 respectively. In this case, gas partial pressures and an amount of exhaust are adjusted such that a total pressure in the film forming chamber 3, which contains at least any one of the reaction gases, the purge gases, and the floating gas, becomes an appropriate pressure in a range of 100 Pa to one ten thousand Pa.

At a point of time when the pressure of the interior reaches a predetermined pressure, the rotor 2 starts being rotated at a rotational speed of 1 revolution per second, for example.

Next, a film forming method will be explained hereunder with reference to FIG. 11A. It is started as shown in FIG. 11A from when the vent hole 16 of the rotor 2 comes to the side of a vent hole 15 in the side bulkhead 1, which introduces the purge gas P2.

As shown in FIG. 11A, when the vent hole 16 of the rotor 2 comes beside the vent hole 15 in the side bulkhead 1 to connect the purge gas supplying portion to the interior of the film forming chamber 3, the purge gas is discharged onto the film forming surface of the substrate 101. At this time, the unnecessary gas remaining on the substrate is pushed away quickly because of the pressure of the purge gas, and then is exhausted from the inside of the reduced pressure vessel as a gas flow toward the exhausting apparatus that is connected to the bottom portion of the reduced pressure vessel.

Then, the rotor 2 is rotated, and then the vent hole 16 of the rotor 2 is moved from the vent hole 15 of the side bulkhead 1 in FIG. 11B to the vent hole 12 of the side bulkhead 1. The residual purge gas is exhausted from the film forming surface of the substrate 101 during this period.

Then, as shown in FIG. 11C, when the vent hole 16 of the rotor 2 comes beside the reaction gas A vent hole 12 of the side bulkhead 1 to connect the reaction gas A supplying portion to the interior of the film forming chamber 3, the reaction gas A is discharged onto the film forming surface of the substrate 101. At this time, the pressure of the reaction gas A is lower than the pressure of the floating gas. It results in suppressing a leakage of the reaction gas A into the clearance between the side bulkhead 1 and the rotor (rotating body) 2.

In contrast, the film forming surface of the substrate 101 is covered with the reaction gas A enough to form one atomic layer, and then the film starts being formed. As shown in FIG. 11D, one atomic layer 102 consisting of A atoms is formed on the substrate 101 until the vent hole 16 of the rotor 2 moves beside a next vent hole 13. This behavior is shown in FIG. 13A. In this case, the reaction gas A is reduced gradually by the exhaust.

Then, as shown in FIG. 11E, when the vent hole 16 of the rotor 2 comes to the side of the vent hole 13 of the side bulkhead 1 to connect the purge gas supplying portion to the interior of the film forming chamber 3, the purge gas is discharged onto the film forming surface of the substrate 101. At this time, the reaction gas A remaining on the substrate is pushed away almost in a moment by the purge gas, and then is exhausted from the inside of the reduced pressure vessel as a gas flow toward the exhausting apparatus that is connected to the bottom portion of the reduced pressure vessel.

Subsequently, the rotor 2 is rotated, and then the vent hole 16 of the rotor 2 is moved from the vent hole 13 of the side bulkhead 1 in FIG. 11F to the vent hole 14 of the side bulkhead 1. The residual purge gas is exhausted from the film forming surface of the substrate 101 during this period.

Then, as shown in FIG. 11G, when the vent hole 16 of the rotor 2 comes beside the reaction gas B vent hole 14 of the side bulkhead 1 to connect the reaction gas B supplying portion to the interior of the film forming chamber 3, the reaction gas B is discharged onto the film forming surface of the substrate 101. At this time, the pressure of the reaction gas B is lower than the pressure of the floating gas. It results in suppressing a leakage of the reaction gas B into the clearance between the side bulkhead 1 and the rotor (rotating body) 2.

In contrast, the film forming surface of the substrate 101 is covered with the reaction gas B enough to form one atomic layer, and then the film starts being formed. As shown in FIG. 11H, one atomic layer 103 consisting of B atoms is formed on the one atomic layer 102 consisting of the A atoms on the substrate 101 until the vent hole 16 of the rotor 2 moves beside the next vent hole 15. This behavior is shown in FIG. 13B. In this case, the reaction gas B is reduced gradually by the exhaust.

Then, returning to FIG. 11A, the reaction gas B is discharged almost in an instant from the interior of the film forming chamber 3 by the discharge of the purge gas. The A atomic layer and the overlying B atomic layer are laminated sequentially every rotation via states in FIGS. 11A to 11H by continuing to rotate the rotor 2. In this case, if the number of revolution of the rotor 2 is set previously from the start to the end, the film in which the A atomic layer and the B atomic layer are laminated alternately can be formed to have a predetermined film thickness in response to the number of revolution.

As described above, according to the film forming method of this embodiment of the present invention, discharge of the reaction gas and discharge of the purge gas are carried out alternately by rotating the rotor 2. Therefore, after one atomic layer is deposited by discharging the reaction gas, the reaction gas remaining on the substrate 101 can be exhausted in a moment by discharging the purge gas. As a result, deposition of a number of atomic layers can be carried out at a high speed.

### (iii) Varieties of the Reaction Gas, the Purge Gas, and the Floating Gas

Explanation will be performed hereunder for varieties of the reaction gas, the purge gas, and the floating gas used in the film forming method by the ALD equipment and the ALD method according to this embodiment. In this case, the above-mentioned reaction gases are merely illustrated by example, and the present invention is not limited to them.

Here, upon forming the film, reaction gases, etc. set forth in the following are employed in appropriate combination to meet to the type of the to-be-formed film. In this case, it is preferable that the reaction gas should be employed in the so-called ALD window temperature range.

(a) Reaction Gas

magnesium (Mg) . . . Cp₂Mg, calcium (Ca) . . . Ca(thd)₂, strontium (Sr) . . . Sr(thd)₂, zinc (Zn) . . . Zn, ZnCl₂, (CH₃)₂Zn, (C₂H₅)₂Zn, cadmium (Cd) . . . Cd, CdCl₂, aluminum (Al) . . . (CH₃)₃Al, (C₂H₅)₃A1, (i-C₄H₉)₃Al, AlCl₃, (C₂H₅O)₃Al, gallium (Ga) . . . (CH₃)₃Ga, (C₂H₅)₃Ga, (C₂H₅)₂GaCl, indium (In) . . . (CH₃)₃In, (C₂H₅)₃In, (C₂H₅)₂InCl, carbon (C) . . . C₂H₂, silicon (Si) . . . Si₂H₆, SiH₄, SiH₂Cl₂, Si₂Cl₆, germanium (Ge) . . . GeH₄, tin (Sn) . . . SnCl₄, lead (Pb) . . . Pb[(OBu^{t})₂]_{m=2,3}, Pb₄O(OBu^{t}) ₆, Pb(thd)₂, Pb(dedtc)₂, nitrogen (N) . . . NH₃, phosphorus (P) . . . PH₃, arsenic (As) . . . AsH₃, antimony (Sb) . . . SbCl₅, oxygen (O) . . . O₂, O₃, H₂O, H₂O—H₂O₂, CxHyOH, sulfur (S) . . . H₂S, selenium (Se) . . . Se, H₂Se, tellurium (Te) . . . Te, titanium (Ti) . . . TiCl₄, Ti(OᵢPr)₄, zirconium (Zr) . . . ZrI₄, ZrCl₄, CpZr(CH₃)₂, Cp₂ZrCl₂ (Cp=cyclopentadienyl), Zr(thd)₄ (thd=3,3,5,5,-tetramethylheptane-3,5-dionate), Zr(OC(CH₃)₃)₄, Zr(OC(CH₃)₃)₂(dmae)₂ (dme=dimethylamino-ethoxide), niobium (Nb) . . . NbCl₅, tantalum (Ta) . . . TaCl₅, molybdenum (Mo) . . . MoCl₅, cerium (Ce) . . . Ce(thd)4, hafnium (Hf) . . . Hf(N(CH₃)(C₂H₅))₄, Hf(N(CH₃)₂)₄, Hf(N(C₂H₅)₂)₄, Hf(NO₃)₄, others . . . (CH₃)₂CHOH, NO₂

Now, out of the above reaction gases, there are the gases that can be used as a dopant gas for giving conductivity to the semiconductor film. These gases can be used properly.

(b) Purge Gas

N₂, He, Ne, Ar, Kr, etc.

(c) Floating Gas

N₂, He, Ne, Ar, Kr, etc.

### Second Embodiment

### (i) Configuration of the ALD Equipment

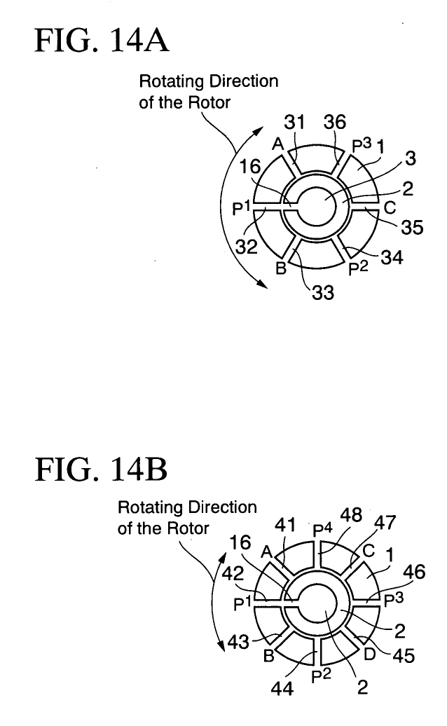

FIG. 14A is a plan view showing a configuration of an ALD equipment as a second embodiment of the present invention.

A difference from the ALD equipment in the first embodiment resides in that the ALD equipment in the second embodiment is provided with three discharge ports 31, 33, 35 from which three type reaction gases A, B, C are discharged. Three discharge ports 32, 34, 36 for purge gases P1 to P3 are provided between respective two ports of the discharge ports 31, 33, 35 for the reaction gases A, B, C respectively. Also, the film forming chamber 3 is constituted by a space of the inner side of the rotor 2 and a space between the upper bulkhead and the substrate holder.

In this case, it is the same as the first embodiment that the rotor 2 having one vent hole 16 is rotated in both rightward and leftward directions. Other configurations are similar to the first embodiment.

When the vent hole 16 of the rotor 2 coincides with one of the discharge ports 31 to 36 by controlling the rightward and leftward rotations of the rotor 2, corresponding one of the reaction gases A to C and the purge gases P1 to P3 is discharged into the interior of the film forming chamber 3.

FIG. 14B is a plan view showing another configuration of the ALD equipment according to the second embodiment.

A difference from the configuration in FIG. 14A is that the ALD equipment is provided with four discharge ports 41, 43, 47, 45 for four type reaction gases A to D. In this case, four discharge ports 42, 43, 46, 48 for purge gases P1 to P4 are provided between respective two ports of the discharge ports 41, 43, 47, 45 for the reaction gases A, B, D, C respectively. Also, the film forming chamber 3 is constituted by a space of the inner side of the rotor 2 and a space between the upper bulkhead and the substrate holder.

In this case, it is the same as the first embodiment that the rotor 2 having one vent hole 16 is rotated in both rightward and leftward directions. Other configurations are similar to those in the first embodiment.

When the vent hole 16 of the rotor 2 coincides with one of the discharge ports 41 to 48 by controlling the rightward and leftward rotations of the rotor 2, corresponding one of the reaction gases A to D and the purge gases P1 to P4 is discharged into the interior of the film forming chamber 3.

In this case, when the ALD equipment in the above second embodiment is computer-controlled, the control can be performed for at least any one of partial pressures of the reaction gases, partial pressures of the purge gases, the partial pressure of the floating gas, an amount of exhaust from the vessel, the rotating direction of the rotor 2, the rotational speed of the rotor 2, and a total rotation history of the rotor 2 from the start to the end of the film formation. When the substrate holder is rotated, control can be performed for the rotating direction or the speed of the substrate holder, or both of them. Accordingly, an automatic control can be achieved for the deposition.

As described above, the ALD equipment of this embodiment is provided with three reaction gas discharge ports or more, and also the rotor 2 can be rotated in both rightward and leftward directions. Therefore, three different atomic layers or more can be deposited while freely controlling constitutional rates of respective atomic layers in the overall deposited film. In addition, since the rotor 2 has a function of switching the reaction gas and the purge gas, the film having any structure can be formed at a high speed only by controlling the rotation history of the rotor 2.

### (ii) Film Forming Method Using the ALD Equipment

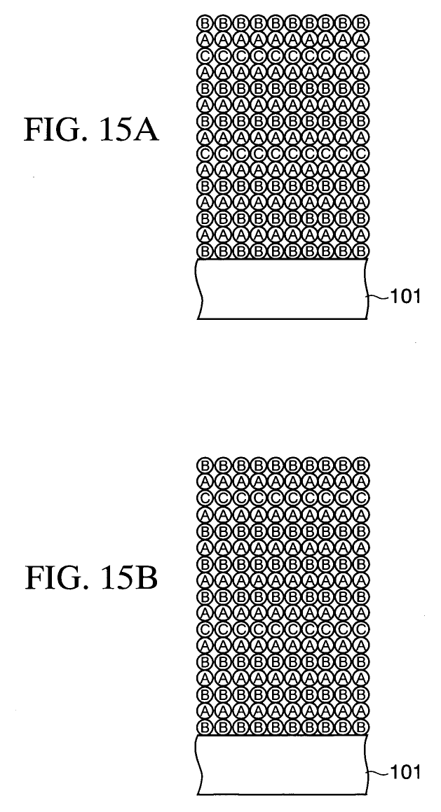

Next, a film forming method using the ALD equipment in the second embodiment will be explained with reference to FIGS. 14A and FIGS. 15A hereunder. In the film forming method in the second embodiment, it is different from the film forming method in the first embodiment that the reaction gases A, B, C and the purge gases P1, P2, P3 are used and in addition the rotor 2 is rotated in both rightward and leftward directions. Now assume that three sets of different reaction gases out of the above reaction gases are used solely or in combination. In the following explanation, these reaction gases are generalized and labeled as A, B, C, and similarly the purge gases are generalized and labeled as P1, P2, P3.

First, the substrate 101 is loaded on the substrate holder, and then the substrate 101 is heated up to a predetermined temperature to satisfy the saturation conditions in which the film can be deposited by respective reaction gases A, B, C every atomic layer. As the case may be, the substrate holder is rotated upon the supporting axis as the rotation axis. Then, all the reaction gases A, B, C and the purge gases P1, P2, P3 are led to the gas discharge ports 31 to 36 at their predetermined pressures, and are brought into such a condition that these gases can be discharged immediately from the gas discharge ports 31 to 36.

Then, the vent hole 16 of the rotor 2 is forced to coincide with the discharge port 32 for the purge gas P1 by rotating the rotor 2. Accordingly, the purge gas P1 is introduced into the film forming chamber 3 via the discharge port 32 and the vent hole 16 to remove the unnecessary gas from the surface of the substrate 101.

Then, the vent hole 16 is forced to coincide with the discharge port 33 for the reaction gas B by rotating the rotor 2 leftward. Accordingly, one B atomic layer is formed on the substrate 101 by introducing the reaction gas B into the film forming chamber 3 via the discharge port 33 and the vent hole 16. Then, the vent hole 16 of the rotor 2 is forced to coincide with the discharge port 32 for the purge gas P1 by rotating the rotor 2 rightward. Accordingly, the purge gas P1 is introduced into the film forming chamber 3 via the discharge port 32 and the vent hole 16 to remove the residual reaction gas B from the surface of the substrate 101.

Then, the vent hole 16 is forced to coincide with the discharge port 31 for the reaction gas A by rotating the rotor 2 further rightward. Accordingly, one A atomic layer is formed on the B atomic layer by introducing the reaction gas A into the film forming chamber 3 via the discharge port 31 and the vent hole 16.

The above steps are three times repeated and, as shown in FIG. 15A, the A atomic layer and the B atomic layer are formed alternately and finally three layers thereof are deposited respectively.

Then, the rotor 2 is rotated rightward so as to force the vent hole 16 of the rotor 2 to coincide with the discharge port 36 for the purge gas P3. Accordingly, the purge gas P3 is introduced into the film forming chamber 3 via the discharge port 36 and the vent hole 16 to remove the residual reaction gas A from the surface of the substrate 101.

Then, the rotor 2 is further rotated rightward to force the vent hole 16 to coincide with the discharge port 35 for the reaction gas C. Accordingly, the reaction gas C is introduced into the film forming chamber 3 via the discharge port 35 and the vent hole 16 so as to deposite one C atomic layer on the A atomic layer.

Then, the rotor 2 is rotated leftward to sequentially execute the purge by the purge gas P3, the deposition of the A atomic layer, the purge by the purge gas P1, and the deposition of the B atomic layer. Then, the rightward rotation and the leftward rotation of the rotor 2 is repeated to sequentially execute the purge by the purge gas P1, the deposition of the A atomic layer, the purge by the purge gas P1, the deposition of the B atomic layer, the purge by the purge gas P1, and the deposition of the A atomic layer.

Then, the rotor 2 is further rotated rightward to sequentially execute the purge by the purge gas P3 and the deposition of the C atomic layer. Then, the rotor 2 is rotated leftward to sequentially execute the purge by the purge gas P3, the deposition of the A atomic layer, the purge by the purge gas P1, and the deposition of the B atomic layer. With the above, as shown in FIG. 15A, the film consisting of multiple atomic layers to contain the C atomic layer between the A atomic layer and the B atomic layer, can be formed on the substrate 101. In this case, if the reaction gas C is the dopant gas, the film can be deposited to put the dopant atomic layer between the deposited layers of the semiconductor layers, for example, so that the semiconductor film with an n-type or p-type conductivity can be formed as a whole.

In this case, by further adding, in contrast to the case in FIG. 15A, the leftward rotation which goes to the discharge port 33 of the reaction gas B from the discharge port 31 of the reaction gas A via the discharge port 32 of the purge gas P1, and the rightward rotation which goes subsequently to the discharge port 31 of the reaction gas A via the discharge port 32 of the purge gas P1, respective depositions of the A atomic layer and the B atomic layer are increased by one layer in contrast to FIG. 15A. It results in a formation of the film shown in FIG. 15B.

As described above, according to the ALD method of the present embodiment, three different atomic layers or more can be deposited while freely controlling constitutional ratios of the atomic layers in the overall deposited film, merely by being provided with three discharge ports or more of the reaction gases and controlling the rotation history of the rotor 2. In addition, since the discharge of the reaction gas and the purge are executed alternately, it is capable of forming the film at a high speed while suppressing generation of defect and contamination of the impurity to the film.

The present invention is explained in detail based on the embodiments as above. A scope of the present invention is not limited to examples shown particularly in the embodiments, and variations of the above embodiments not to depart from the gist of the invention are contained in the scope of the present invention.

For example, in the film forming equipment in the first and second embodiments, a size of the discharge port of the purge gas is set equal to a size of the discharge port of the reaction gas. But the discharge port of the purge gas may be enlarged to execute the purge quickly without fail. Otherwise, it may be provided with a plurality of discharge ports of the purge gas, which can discharge the purge gas simultaneously.

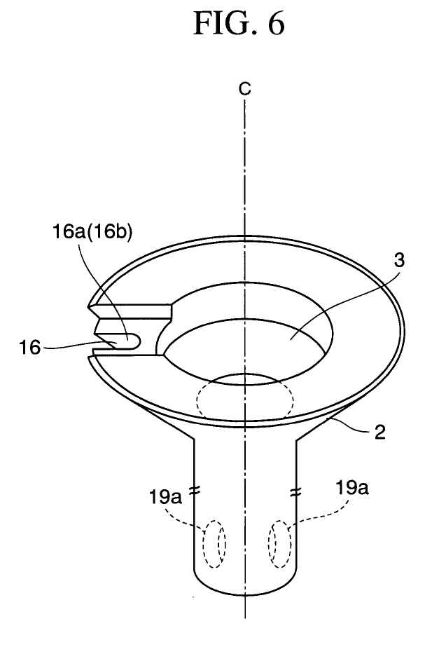

Also, it may be provided with one third vent hole of the rotor 2, but, as the case may be, it may be provided with two vent holes or more. Also, the third vent hole as the through hole is used as the flow path of the rotor 2 shown in FIG. 2. However, for the through hole, a notched vent portion formed by cutting off a part of the peripheral portion of the rotor 2 to flow the gas, as shown in FIG. 6, may be used as the gas flow path.

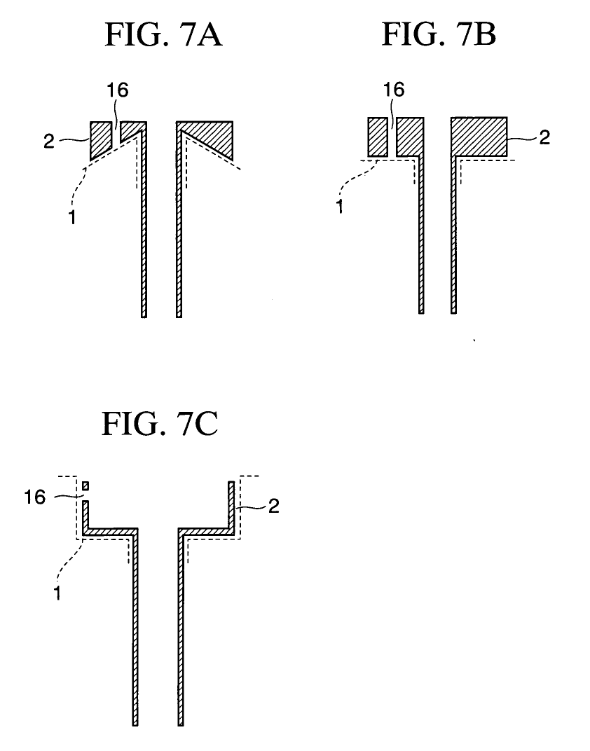

Also, in the above embodiments, the upper inner surface of the side bulkhead 1 and the upper outer surface of the rotor 2 are formed like the conical shape that is extended upwardly. In this case, the inclination angle of the conical shape may be changed appropriately within a range of 0 to 90 degree. In particular, when the inclination angle of the upper outer surface of the rotor 2 is set to 90 degree, i.e., when the upper outer surface of the rotor 2 has a flat surface, the shape of the rotor 2 is shown in FIGS. 7B and 7C. Here, assume that the upper outer surface of the rotor 2 signifies the surface that receives a floating force applied by the floating gas on the surface of the side bulkhead 1 of the vessel. Alternately, as shown in FIG. 7A, the upper outer surface of the rotor 2 may be formed like a conical shape that is extended downwardly. In FIGS. 7A to 7C, a symbol 16 is the third vent hole provided in the rotor 2.

Also, the substrate holder 4 is formed to hold the substrate thereon. But the substrate holder 4 may be formed to hold the substrate thereunder.

Also, the substrate holder 4 is fixed. But the. substrate holder 4 may be set to rotate in one direction or in both rightward and leftward directions. In this case, a well-known method such as a magnetic sealing may be employed as a method of sealing the reduced pressure vessel.

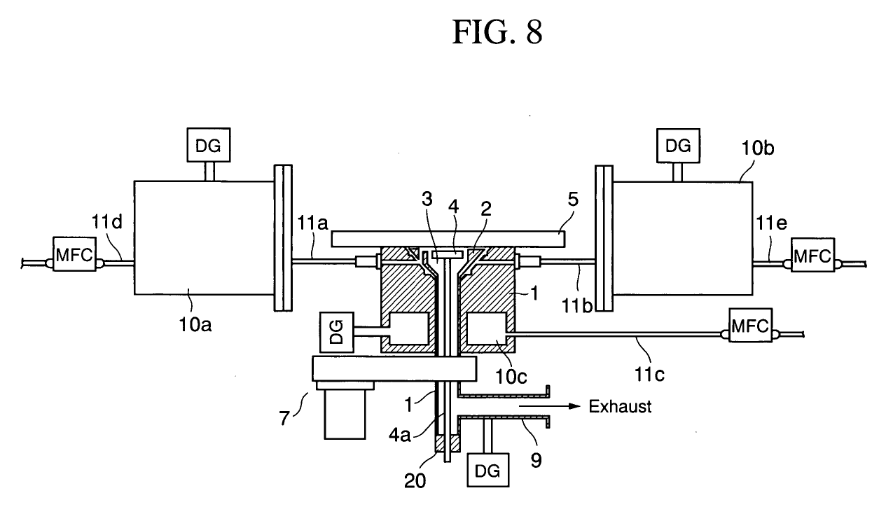

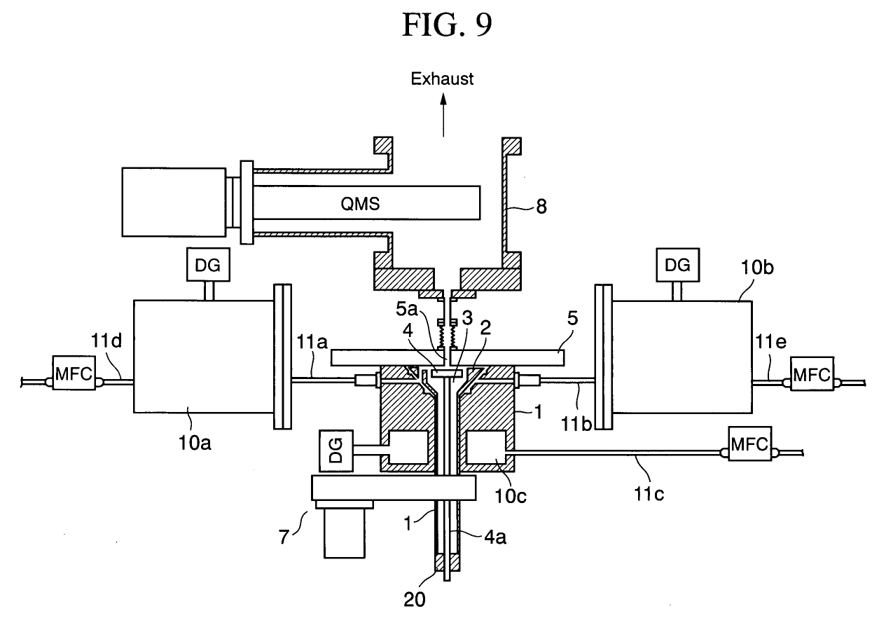

In addition, the exhausting apparatus is connected to the upper portion and the lower portion of the reduced pressure vessel respectively. But the exhausting apparatus may be connected to the lower portion of the reduced pressure vessel to exhaust the reaction gases, etc. from the lower portion, as shown in FIG. 8, and also may be connected to a vent hole 5a provided in the upper bulkhead 5, as shown in FIG. 9. In FIGS. 8 and 9, the elements indicated by the same symbols as those in FIG. 1 correspond to those in FIG. 1.

Further, in the first embodiment, only the discharge port 17a for the floating gas as well as the discharge ports 12a to 15a for the reaction gases and the purge gases is provided on the flat or cone-shaped inner surface of the side bulkhead 1 of the reduced pressure vessel. In this case, as shown in FIG. 10B, an exhaust hole 18 which passes through the side bulkhead 1 of the reduced pressure vessel and an inner exhaust port 18a at which the exhaust hole 18 is terminated may be provided on the flat or cone-shaped inner surface of the side bulkhead 1 of the reduced pressure vessel in addition to the discharge port 17a for the floating gas. Thereby, the floating gas discharged from the discharge port 17a may be exhausted from the inner exhaust port 18a through the exhaust hole 18. Accordingly, the partial pressure of the floating gas can be controlled variously by the discharging and exhausting operations. In FIG. 10B, a symbol 18b denotes an outer exhaust port as an outer terminating portion of the exhaust port 18. Other elements indicated by the same symbols as those in FIGS. 1 to 4 correspond to those in FIGS. 1 to 4.

Moreover, the inner permanent magnet 19a and the outer permanent magnet 19b to rotate the rotor 2 are arranged to employ their repulsive force between the S poles. But these permanent magnets may be arranged to employ their repulsive force between the N poles. Also, an electromagnet may be employed in place of the permanent magnet. In addition, various well-known means may be employed as the rotating means.

Besides, different reaction gases are discharged from the discharge ports of the reaction gases respectively, in the first embodiment, to laminate alternately the atomic layers 102, 103 made of different atoms of the A atom and the B atom, and in the second embodiment, to laminate the atomic layer consisting of different atoms of the A atom, the B atom, and the C atom with an appropriate repetition. But the same atomic layers may be laminated by discharging the same reaction gas to have a predetermined film thickness.

Also, two to four discharge ports for the reaction gases and the purge gases are provided alternately around the substrate respectively, but such discharge ports may be provided one by one. Or, five gas discharge ports or more may be provided alternately respectively. In this case, the same gas may be discharged, or different gases may be discharged respectively. Also, if five gas discharge ports are provided respectively, the same reaction gas may be discharged plural times during when the rotor is rotated once around the circumference. Further, as the case may be, the discharge ports for the reaction gas and the purge gas are not always alternately provided, and only the discharge ports for the reaction gas may be provided without provision of the discharge ports for the purge gas.

Also, the rotational speed of the rotor 2 is set to one revolution/second. But such rotational speed of the rotor 2 may be changed appropriately to meet to the type of source, the film forming temperature, or the like, or to adjust a deposition speed.

In addition, in the film forming equipment of the present invention, a space can be secured over the substrate holder. Therefore, the space may be provided with a measurement observing means capable of observing sequentially the film forming situation, an energy supply source for the reaction gas for making the deposition smooth and easy, an infrared or lamp heating means as a heating means for the substrate, a catalyst plate for activating the gas, a plasma generating means, etc.

Also, the equipment having the configuration of the present invention is applied to the ALD equipment. But such equipment may be applied to other film forming equipments or the etching equipment.

As described above, according to the processing equipment of the present invention, one gas discharge port or more are arranged around the substrate holder, and then the gas is discharged onto the substrate holder from the gas discharge port when the discharge port coincides with the vent hole of the rotating body based on the rotation control of the rotating body.

In other words, the rotating body has a gas switching function during its rotation and therefore an amount of discharged gas can be controlled with good precision. As a result, the film formation or the etching can be carried out with good controllability.

Especially, in the situation that the processing equipment of the present invention is applied to the ALD equipment, if the reaction gas discharge ports are provided as one gas discharge port or more, the atomic layers can be deposited every layer based on the rotation control of the rotating body. Also, the deposition speed can be simply adjusted merely by adjusting the rotational speed of the rotating body. In addition, the reaction gas discharge port and the purge gas discharge port are provided as one gas discharge port or more, then these discharge ports are arranged alternately around the substrate holder, and then the rotating body is rotated. With this, the reaction gas can be purged in a moment by the purge gas after one atomic layer is deposited by the reaction gas. Therefore, the deposition of one atomic layer or more can be carried out at a high speed.

Also, since the rotating body is rotated while floating over the side bulkhead of the vessel, it is capable of facilitating the positional accuracy between the side bulkhead of the vessel and the rotating body, and thus it is capable of implementing the stable and very narrow clearance. Also, since the rotating body is not fixed, it is capable of disassembling simply such rotating body, and thus it is capable of facilitating the cleaning of the rotating body and the inner side of the vessel including the gas supplying mechanism after the disassembling of the rotating body.

Also, the processing method of the present invention is capable of controlling an amount of discharged gas with good precision by rotating the rotating body. Therefore, the film thickness control or the etching control can be carried out with good precision.

In particular, in the situation that the processing method of the present invention is applied to the ALD method, since the discharge of the reaction gas and the discharge of the purge gas are executed alternately by rotating the rotating body, the exhaust of the reaction gas can be carried out in an instant by the purge gas after one atomic layer is deposited by the reaction gas. As a result, a number of atomic layers can be deposited at a high speed.

What is claimed is:

1. A processing equipment comprising:
a vessel having one gas discharge port or more;
a substrate holder provided in the vessel to load a substrate thereon; and
a rotating body provided between the substrate holder and a side wall of the vessel to rotate around the substrate holder and having one vent hole or notched vent portion or more;
wherein a gas is discharged onto the substrate holder from the gas discharge port when the gas discharge port coincides in position with the vent hole or notched vent portion of the rotating body by rotation control of the rotating body.

2. A processing equipment according to claim 1, wherein the one gas discharge port or more are a reaction gas discharge port and a purge gas discharge port.

3. A processing equipment according to claim 2, wherein the reaction gas discharge port and the purge gas discharge port are arranged alternately along a periphery of the substrate holder.

4. A processing equipment according to claim 1, wherein at least an upper inner surface of the side wall of the vessel has a flat shape or a cone-like shape, an upper outer surface of the rotating body has a flat shape or a cone-like shape in conformity with the flat shape or the cone-like shape of the side wall of the vessel, and a floating gas discharge port is provided on an inner surface of a flat or cone-shaped side wall of the vessel, and
the rotating body is floated so as to space from an inner surface of the side wall of the vessel by discharging the floating gas.

5. A processing equipment according to claim 4, wherein a plurality of floating gas discharge ports are provided along a circumference of the flat or cone-shaped inner surface of the side wall of the vessel.

6. A processing equipment according to claim 4, wherein an exhaust port is provided on the flat or cone-shaped inner surface of the side wall of the vessel, and the floating gas discharged is exhausted via the exhaust port.

7. A processing equipment according to claim 1, further comprising means for adjusting a pressure of the gas and suppressing a pressure variation of the gas discharged from the gas discharge port.

8. A processing equipment according to claim 1, wherein the substrate holder is supported by a supporting axis, and the substrate holder is rotated upon the supporting axis.

9. A processing equipment according to claim 1, further comprising means for heating the substrate loaded on the substrate holder.

10. A processing equipment according to claim 1, wherein an exhausting means for reducing a pressure in an inside of the vessel is connected to the vessel.

11. A processing equipment according to claim 1, further comprising a controlling means for adjusting at least any one of a partial pressure of the reaction gas, a partial pressure of the purge gas, a partial pressure of the floating gas, an amount of exhaust in the vessel, a rotating direction of the rotating body, a rotational speed of the rotating body, a total rotation history of the rotating body from a start to an end of a film formation, a rotating direction of the substrate holder, and a rotational speed of the substrate holder.

12. A processing method comprising the steps of:
arranging one gas discharge port or more, which discharge a gas, around a periphery of a substrate;
preparing a rotating body, which is rotated around the substrate and having one vent hole or notched vent portion therein, between the substrate and the gas discharge port; and
discharging the gas onto the substrate holder when the gas discharge port coincides in position with the vent hole or notched vent portion of the rotating body by rotation control of the rotating body, and thus processing the substrate by the discharged gas.

13. A processing method according to claim 12, wherein the one gas discharge port or more are a reaction gas discharge port and a purge gas discharge port, and the reaction gas and the purge gas are discharged alternately onto the substrate by the rotation control of the rotating body.

14. A processing method according to claim 12, wherein one atomic layer or more are formed on the substrate.
